(19) United States
(12) Patent Application Publication
(10) Pub. No.: US 2017/0057810 A1
(43) Pub. Date: Mar. 2, 2017

(54) Strain Reduction and Sensing on Package Substrates

(71) Applicant: Apple Inc., Cupertino, CA (US)

(72) Inventors: Krishna Prasad Vummidi Murali, Sunnyvale, CA (US); Christopher C. Painter, Dublin, CA (US); Kuan-Lin Chen, Sunnyvale, CA (US)

(73) Assignee: Apple Inc., Cupertino, CA (US)

(21) Appl. No.: 15/253,711

(22) Filed: Aug. 31, 2016

Related U.S. Application Data
(60) Provisional application No. 62/213,055, filed on Sep. 1, 2015.

(51) Int. Cl. B81B 7/00; B81C 1/00

(52) U.S. Cl. CPC B81B 7/0048; B81C 1/00325; B81B 2203/0127; B81B 2203/0163; B81B 2207/012; B81B 2207/096; B81C 2203/0792

(57) ABSTRACT

A strain measurement platform that comprises of a strain die that can be embedded inside a package substrate or have its own substrate with through silicon vias (TSVs) is disclosed. The strain die comprises a body and a base. The base is coupled to the body with strain enhancing structures. Strain enhancing structures are formed on the strain die to amplify the strain signals locally, while also acting as strain and vibration isolators. Strain sensors are formed on or around the strain enhancing structures at locations of maximum strain. The strain sensors can be piezo-resistors, piezo-junctions or piezo-electrics. Strain enhancing structures are implemented either as compliant springs or as a thin membrane over which the base is suspended. A package stack can be mounted on top of the strain die and electrically connected to a strain measuring platform. Some example process flows for fabricating strain die are also disclosed.

### CROSS-REFERENCE TO RELATED APPLICATION

This application claims priority to U.S. Provisional Patent Application No. 62/213,055, filed Sep. 1, 2015, the entire contents of which are incorporated herein by reference.

### TECHNICAL FIELD

This disclosure relates generally to integrated circuit (IC) and micro-electro-mechanical systems (MEMS) packaging, and more particularly to reducing the effects of package strain induced due to mechanical and thermal effects on MEMS and IC performance.

### BACKGROUND

The performance of modern sensors, including gyroscopes, accelerometers, barometers, hygrometers, magnetometers and thermometers is often affected adversely by mechanical strain induced by assembly and change in environmental conditions such as temperature and humidity. Mechanical strain has a deleterious effect on sensor operation, leading to variations in noise, offset and sensitivity. Mechanical strain effects the sensor through deformation of the sensing element, which shifts capacitive gaps, changes spring constants due to strain, etc., yielding erroneous outputs and changes in temperature sensitivity. While repeatable strain effects over temperature can be partly mitigated through temperature-based compensation output models, these techniques cannot capture strain changes due to humidity or changes in mechanical boundary conditions.

### SUMMARY

A strain measurement platform that comprises a strain die that can be embedded inside a package substrate or have its own substrate with through silicon vias (TSVs) is disclosed. The strain die comprises a body and a base. The base is coupled to the body with strain enhancing structures. Strain enhancing structures are formed on the strain die to amplify the strain signals locally, while also acting as strain and vibration isolators. Strain sensors are formed on or around the strain enhancing structures at locations of maximum strain. The strain sensors can be piezo-resistors, piezo-junctions or piezo-electrics. Strain enhancing structures are implemented either as compliant springs or as a thin membrane over which the base is suspended.

A package stack can be mounted on top of the strain die and electrically connected to the strain measuring platform. The package stack can include a MEMS die attached to an Application-Specific Integrated Circuit (ASIC) die using, for example, a die-attach film (DAF). In some implementations, the strain signals are routed to the strain detection circuitry located in the strain die itself. The strain detection circuitry can be designed and fabricated using conventional Complimentary Metal-Oxide Semiconductor (CMOS) processes, where the strain enhancing structure and isolation structure are fabricated as a part of post-CMOS MEMS process steps. In some implementations, the strain signal is routed to one or more layers of the package stack (e.g., on the ASIC die) and/or to circuitry outside the sensor package.

The strain die can be attached to or embedded in a package substrate (e.g., a land grid array (LGA) or ball grid array (BGA)) to form a package stack. The conductive paths carrying the strain signals can be routed through different layers of the package stack. In some implementations, the strain sensors can be fabricated in silicon integrated into an etched diaphragm to enhance the strain signal for improved detection. In some implementations, the strain sensors can be formed on the backside of the MEMS die or on the MEMS cap wafer. In some implementations, the strain sensors can be formed on the front side and/or backside of the ASIC die.

Particular implementations disclosed herein realize one or more of the following advantages. The performance of sensors in integrated circuit or MEMS packages is improved by introducing a strain die with strain sensors into the package stack. The strain enhancing structures are designed to amplify strain signals locally, while also acting as strain and/or vibration isolators. The strain die can be embedded in a package substrate to reduce the height of the package. The strain sensor can also have its own substrate with TSVs to reduce the overall height of the package. The disclosed implementations enable a sensor package to monitor strain signals while the sensor package is deployed in another device or system and to compensate for the strain in real-time.

The details of one or more implementations are set forth in the accompanying drawings and the description below. Other features, aspects, and advantages will become apparent from the description, the drawings, and the claims.

### BRIEF DESCRIPTION OF THE DRAWINGS

FIGS. 1A-1E are views of a strain die with integrated strain sensors, according to an embodiment.

FIG. 2A-2C are views of a strain die that also acts as a package substrate, according to an embodiment.

FIGS. 3A-3F are views of alternative embodiments of strain dies with integrated strain sensors, according to an embodiment.

FIG. 4 is a cross-sectional view of a strain die with top side processing, according to an embodiment.

FIGS. 5A-5E are views of alternative embodiments of strain dies with integrated strain sensors, according to an embodiment.

FIGS. 6A and 6B are views of strain sensors integrated into an etched diaphragm to enhance strain signals for improved detection, according to an embodiment.

FIGS. 7A-7C are views of a strain die attached to a package substrate and piezo-resistors ion-implanted in a Rosette or Wheatstone configuration on the back side of a MEMS die to detect strain, according to an embodiment.

FIGS. 8A-8C are views of a strain die attached to a package substrate and piezo-resistors ion-implanted in a Rosette or Wheatstone configuration on the front and back side of an ASIC die to detect strain, according to an embodiment.

FIGS. 9-1 to 9-14 is a process flow for fabricating a strain die to be embedded in a package substrate, according to an embodiment.

FIGS. 10-1 to 10-21 is a process flow for fabricating a strain die that also acts as a package substrate, according to an embodiment.

### DETAILED DESCRIPTION

Several factors contribute to mechanical strain on a sensor package. Common sensor packages such as an LGA and BGA employ soldered or epoxied electrical connections that provide limited mechanical compliance. These connections are capable of transmitting large amounts of mechanical stress between a printed circuit board (PCB) and the sensor package. Epoxies and other under fill materials have coefficients of thermal expansion that differ from those of the sensor package and PCB, and transmit mechanical stress to sensor packages under thermal cycling. Substrate encapsulation compounds transmit moisture absorption induced hygroswelling mechanical stress to the sensor stack due to changes in humidity. Mechanical bending of the PCB transmits strain to sensor packages through the soldered or epoxied electrical connection to the PCB. The PCB and sensor packages have different coefficients of thermal expansion and transmit strain to the sensors through their soldered or epoxied electrical connections. Flexure of the PCB from vibrations imparts strain to sensors through their soldered or epoxied electrical connections to the PCB.

The mechanical strain induced from the PCB is transmitted through the different layers of the package stack, such as the ASIC die, MEMS die and DAF. For a general package structure, the strain transmitted through the different layers reduces as it travels from the package substrate (bottom most layer) to the top of the package stack. Therefore, the system disclosed herein is optimized to sense strain at the substrate level. Furthermore, the strain sensors are comprised of strain enhancing structures to increase or amplify the strain signals locally. In some implementations, the strain enhancing structures also isolate the package stack from mechanical strain and vibration. The strain data is used to compensate the MEMS sensor output for strain induced offset drifts in real time.

### Example Strain Dies

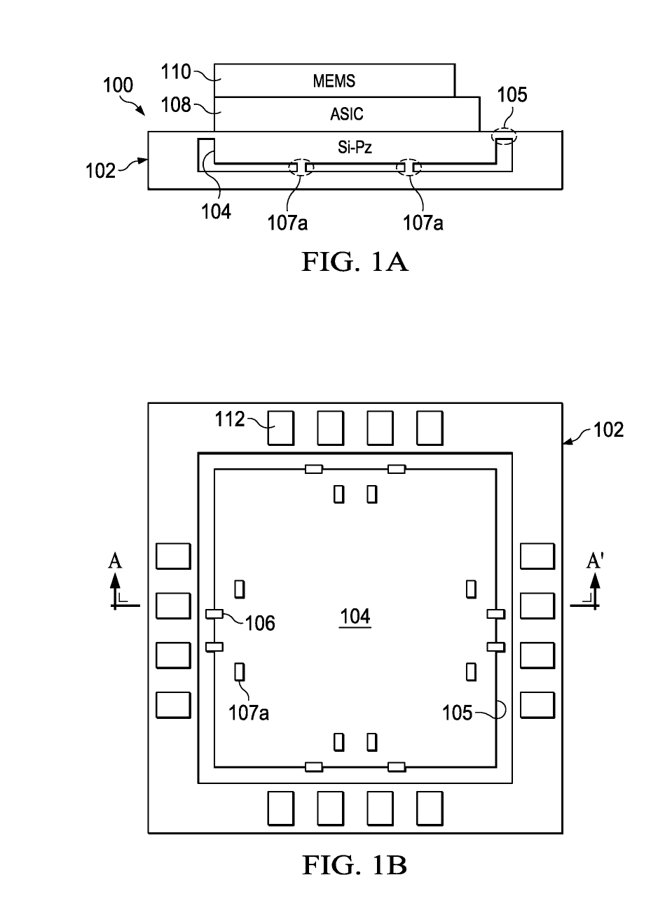

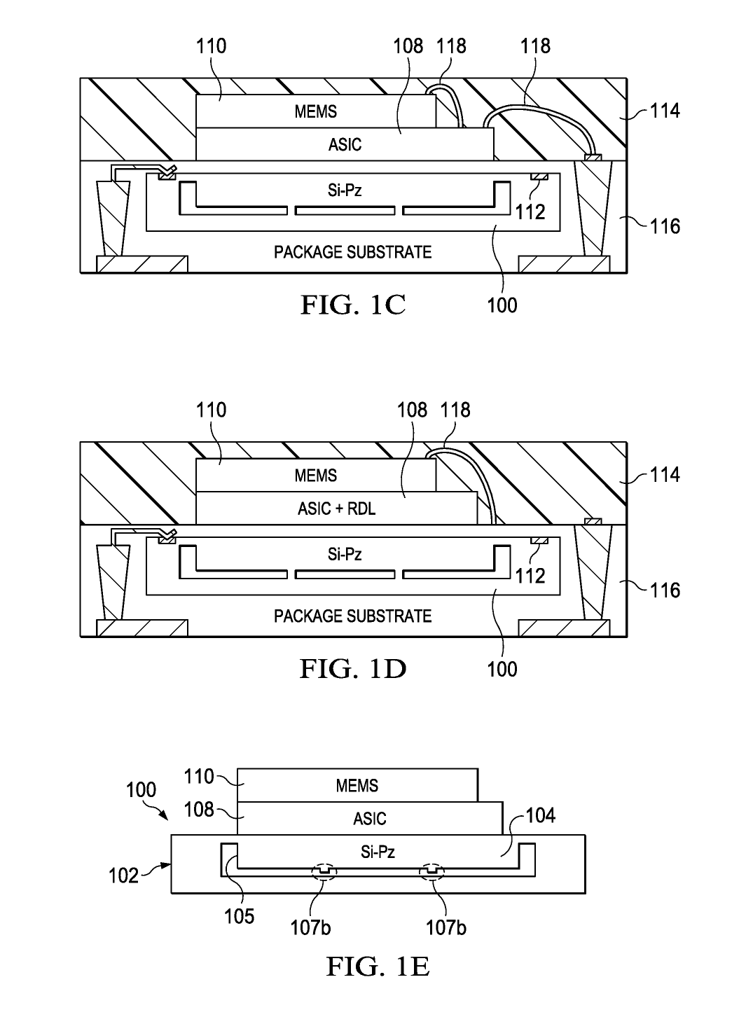

FIGS. 1A and 1B are views of a strain die with integrated strain sensors, according to an embodiment. FIG. 1A is a cross-sectional view along the AA′ plane of FIG. 1B and FIG. 1B is a top view looking down on the strain die plane (a plane perpendicular to the AA′ plane) with the package stack removed. Strain die 100 (Si-Pz) is made of silicon and includes body 102 and embossed base 104. Base 104 supports a package stack comprising ASIC die 108 and MEMS die 110. Base 104 provides a stiff platform for the package stack mounted on top. Base 104 is suspended by thin compliant membrane 105 which acts as a strain enhancing structure. Base 104 concentrates strain induced packaging effects around membrane 105 so the effects can be sensed more effectively by strain sensors 106 disposed around membrane 105 (e.g., doped PzR implants). Strain sensors 106 are laid out in four Wheatstone bridge configurations. Each bridge is comprised of four strain sensors where two of the four strain sensors are located in regions of maximum strain and the other two are located in area of minimum strain. Membrane 105 also isolates base 104 from package induced strain. In an embodiment, base 104 includes one of two structures on its bottom side to prevent excess force from crashing base 104 onto body 102, resulting in permanent structural damage. A first structure is mechanical support 107a shown in FIG. 1A and the second structure is over-travel mechanical stop 107b shown in FIG. 1E. Over-travel mechanical stop 107b is designed to provide a small air-gap between the stop and body. By contrast, mechanical support 107a is fully connected to the body. Based on the design of the strain die, either structure can be fabricated. A dedicated strain IC (not shown) can be fabricated in base 104 for detecting and processing strain signals. Bond pads 112 disposed around body 102 route raw or processed strain signals to ASIC die 108 or outside the package.

Referring to FIGS. 1C and 1D, a completed package is shown with plastic mould material 114 to protect the wire-bond and the package stack from the environment. FIG. 1C shows ASIC die 108 without Redistribution Layer (RDL) and FIG. 1D shows ASIC die 108 with RDL. In both FIGS. 1C and 1D, strain die 100 is embedded into package substrate 116 to reduce the package height. In an embodiment, ASIC die 108 is wire bonded individually to package substrate 116 using wire bonds 118. Strain die 100 is connected to package substrate 116 via bond pads 112 shown in FIG. 1B and MEMS die 110 is wire bonded to the top of ASIC die 108 using wire bonds 118. In another embodiment, ASIC die 108 has an RDL that is flip chip bonded to package substrate 116 and MEMS die 110 is wire bonded directly to package substrate 116, as shown in FIG. 1D.

Because mechanical strain detection becomes more difficult as the strain is transmitted through the different layers of the package stack, it is important to detect the strain at its source or where the strain is maximum. Strain induced on strain sensors can be measured, for example, using a Wheatstone bridge circuit (half or full). A single strain sensor can be configured for measurement along a single axis or a plurality of strain sensors can be oriented in a desired configuration (e.g., a Rosette configuration) to detect stress/strain in X, Y directions and along desired angles (e.g., +/−45 degree angles). In the embodiment shown, the strain sensors are piezo resistor (PzR) strain sensors. However, other strain sensors can be used with the disclosed embodiments. For example, a piezo junction (PzJ) strain sensor can be used to detect strain due to a change in bandgap and a piezo electric (PzE) strain sensor can be used to detect strain due to a change in polarization voltage.

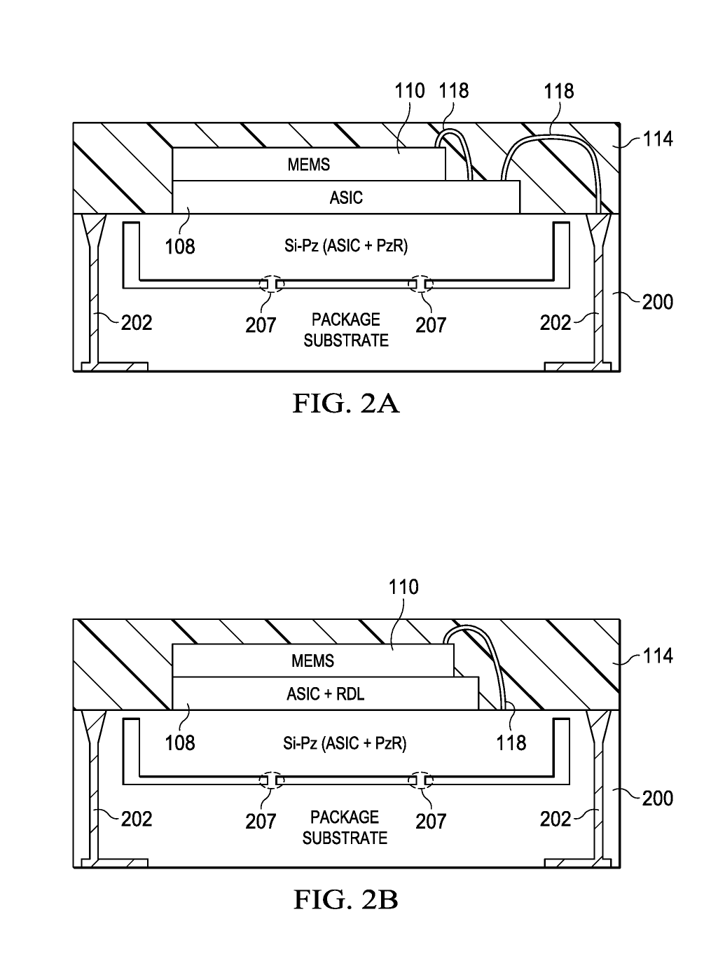

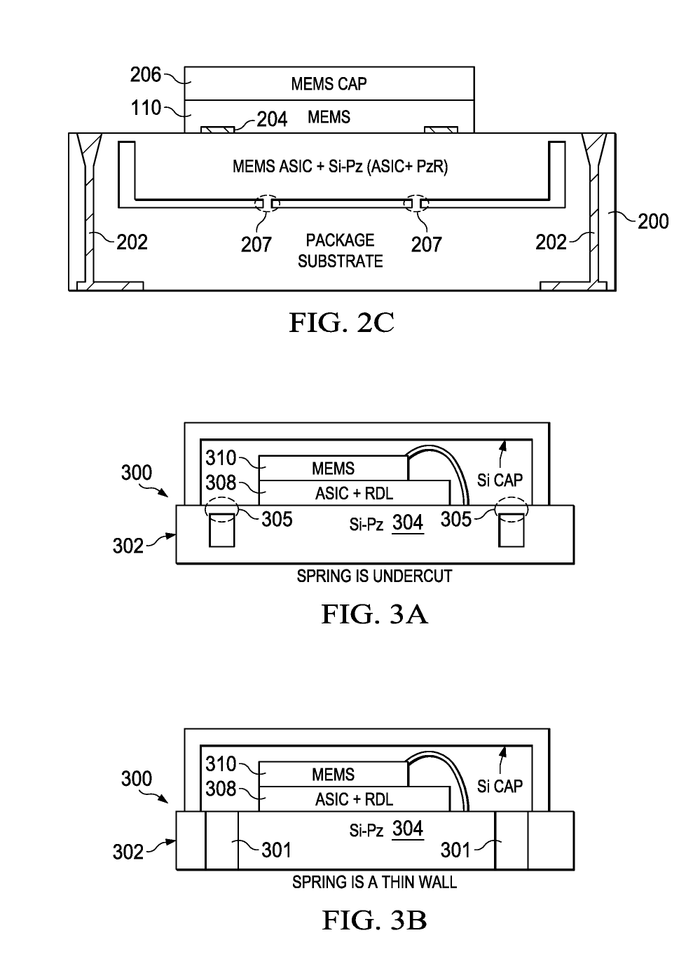

FIGS. 2A-2C are cross-sectional views of strain die 200 that also acts as a package substrate, according to an embodiment. The functionality of strain die 200 is similar to the functionality of strain die 100. The difference is the body of strain die 200 can substitute for package substrate 116. TSVs 202 enable connectivity to outside the package. ASIC die 108 can be wire bonded to strain die 200 using wire bonds 118 and MEMS die 110 can be wire bonded to ASIC 108 as shown in FIG. 2A, or ASIC die 108 can include an RDL that is flip chip bonded to strain die 200 and MEMS die 110 is wire bonded directly to strain die 200 using wire bond 118 as shown in FIG. 2B. In an embodiment, a dedicated strain IC (not shown) separate from ASIC die 108 can be fabricated in the base of strain die 200 to detect, process and condition the strain signals. In an embodiment, the base includes mechanical support 207 on its bottom side to prevent excess force from crashing the base onto the body. Over-travel stops can also be used as shown in FIG. 1E.

FIG. 2C is a cross-sectional view of strain die 200 with embedded MEMS CMOS ASIC electronics. If an additional dedicated strain IC is embedded in the base of strain die 200, the same silicon can be used for both MEMS ASIC and the strain IC. The MEMS ASIC is electrically interconnected to MEMS die 110 by metal layer interconnect 204. MEMS cap 206 protects MEMS die 110 from the environment. This embodiment does not require wire bonds and plastic mould to protect the wire bonds. This embodiment also reduces the overall package height.

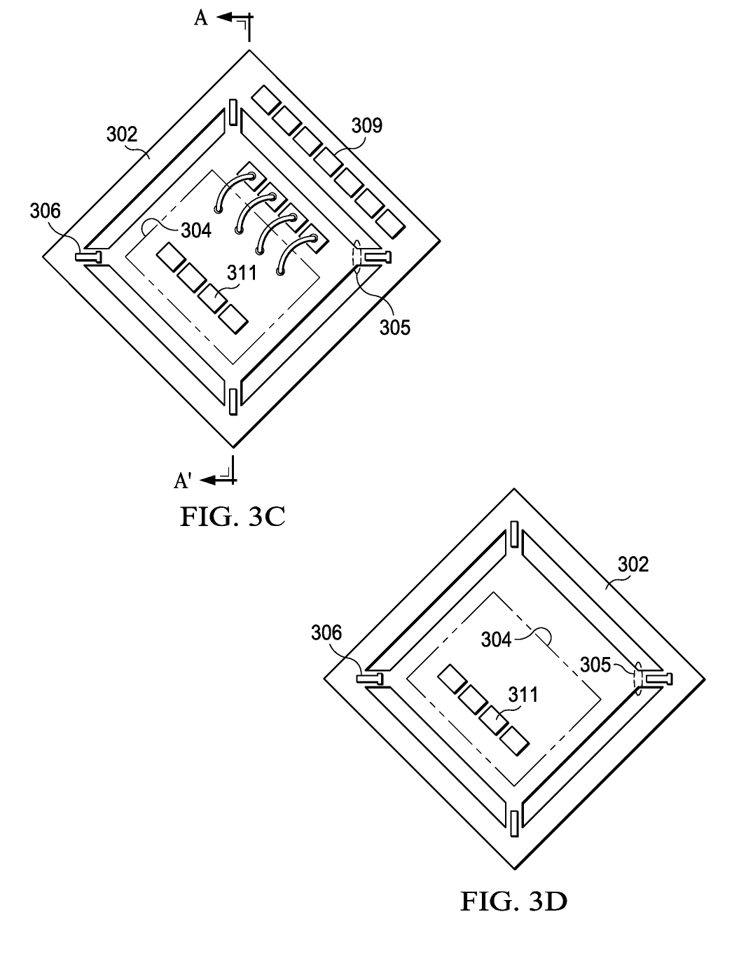

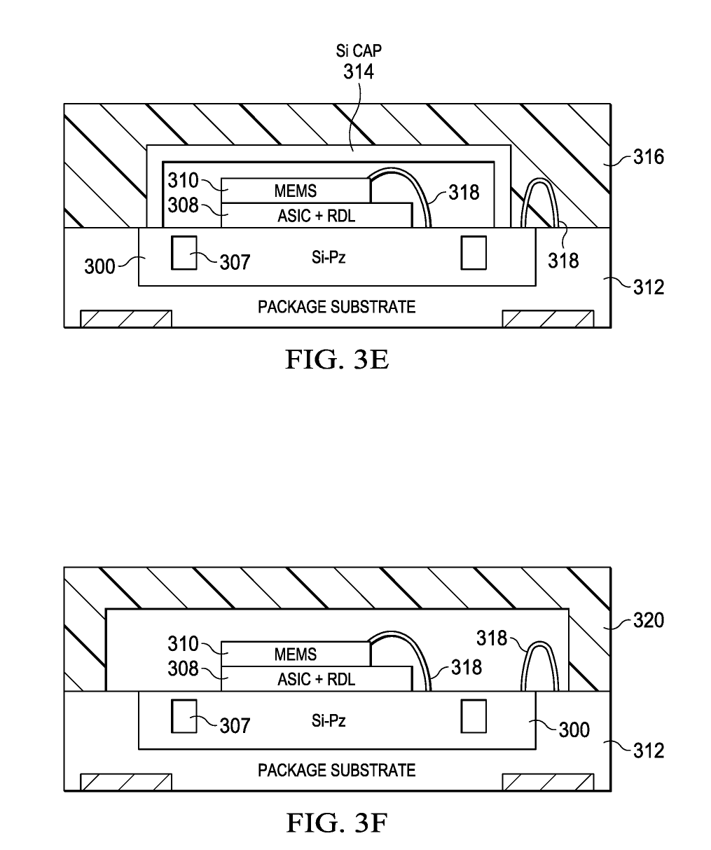

FIGS. 3A-3F are views of alternative embodiments of strain dies with mechanically compliant springs. FIGS. 3A, 3B, 3E and 3F are cross-sectional views along the AA′ plane of FIG. 3C and FIGS. 3C and 3D are top views looking down on the strain die plane (a plane perpendicular to the AA′ plane) with the package stack removed.

Referring to FIGS. 3A-3C, strain die 300 is made of silicon and includes body 302 and base 304. Base 304 supports a package stack comprising ASIC die 308 and MEMS die 310. Base 304 provides a stiff platform for the package stack mounted on top. Base 304 is attached to body 302 by four mechanically compliant springs which also act as strain enhancing structures. FIG. 3A shows strain die 300 with undercut springs 305. FIG. 3B shows an alternative embodiment of strain die 300 with thin wall springs 301. Other embodiments may include more or fewer springs and a combination of undercut springs 305 and thin wall springs 301. Base 304 concentrates strain induced packaging effects around undercut springs 305 (or other locations of maximum strain) so the effects can be sensed more effectively by strain sensors 306 formed on undercut springs 305 (e.g., doped PzR implants). Base 304 is shown with RDL 311 of ASIC die 308. Under cut springs 305 also provide strain isolation to base 304. Bond pads 309 disposed around body 302 route raw or processed strain signals and the MEMS and ASIC signal to the outside of the package. FIG. 3D is a top view of strain die 300 without wire bond pads 309.

Referring to FIG. 3E, strain die 300 is embedded into package substrate 312 (e.g., an LGA substrate) to reduce the overall package height. Silicon cap 314 is bonded on to strain die 300 and encloses ASIC die 308 and MEMS die 310. Silicon cap 314 prevents plastic mould material 316 from entering undercut 307 formed in strain die 300. In an embodiment, MEMS die 310 is wire bonded individually to strain die 300 and the strain die is wire bonded to package substrate 312 using wire bonds 318. FIG. 3F is a cross-sectional view of strain die 300 with plastic or metal lid 320 and no silicon cap 314.

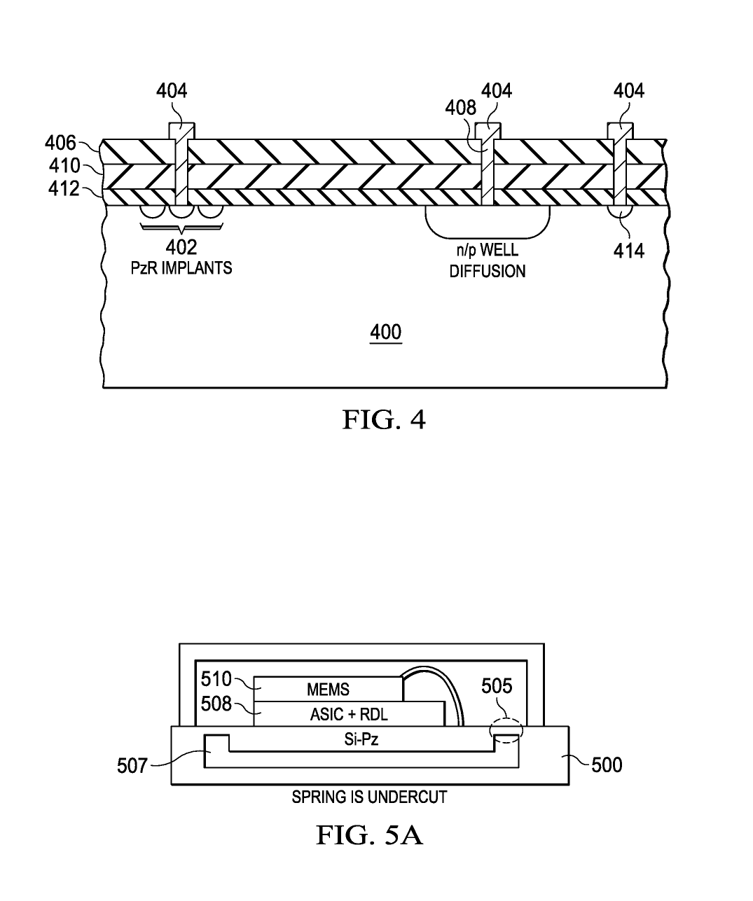

FIG. 4 is a cross-sectional view of a strain die 400 showing details of top side processing. Strain sensors 402 are fabricated in strain die 400 near or around locations of maximum stress, such as near or around strain enhancing structures (e.g., springs). In some implementations, n/p diffusion can be used for temperature sensing and piezo-junctions. In the example shown, metal lines 404 are formed on first dielectric layer 406 (e.g., borophosphosilicate glass (BPSG)). Vertical conductive paths 408 extend through first dielectric layer 406, second dielectric layer 410 (e.g., tetraethylorthosilicate (TEOS)) and silicon oxide (SiO) layer 412 to connect to strain sensors 402. Mechanical strain in strain die 400 causes a change in electrical resistivity of strain die 400. Strain sensors 402 can be fabricated using wide variety of piezo resistive materials, but are shown FIG. 4 as diffused PzR. In some implementations, a PzR implant can include two contact diffused n- or p-wells within a p− or n− substrate. Additional p+ or n+ plus diffusions can be used to facilitate ohmic contacts 414 to strain die 400.

In an embodiment, the strain die can include a temperature sensor (not shown in figures) to compensate for the temperature coefficient of sensitivity of the strain sensing elements (e.g., piezo-resistive implants). The strain sensing elements can be piezo-junction or piezo-electric as well. The temperature sensor can be fabricated in the same die as the strain sensor. The temperature sensor can be implemented in many ways, either as a p-n junction diode whose band gap varies as a function of temperature or a set of p+ and n+ doped resistors in a Wheatstone bridge configuration whose output voltage is a function of temperature.

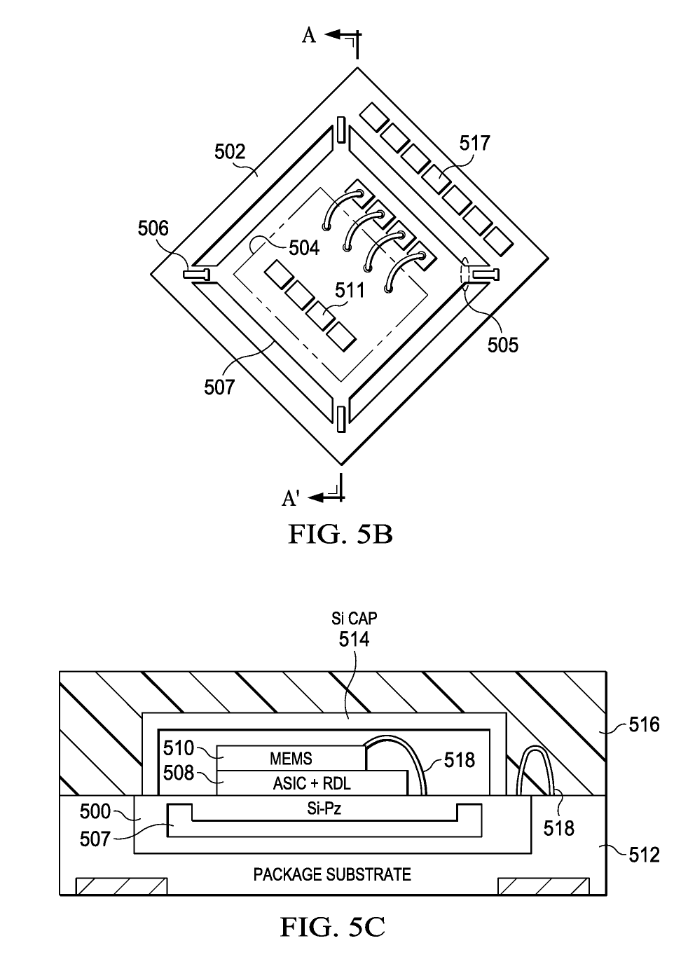

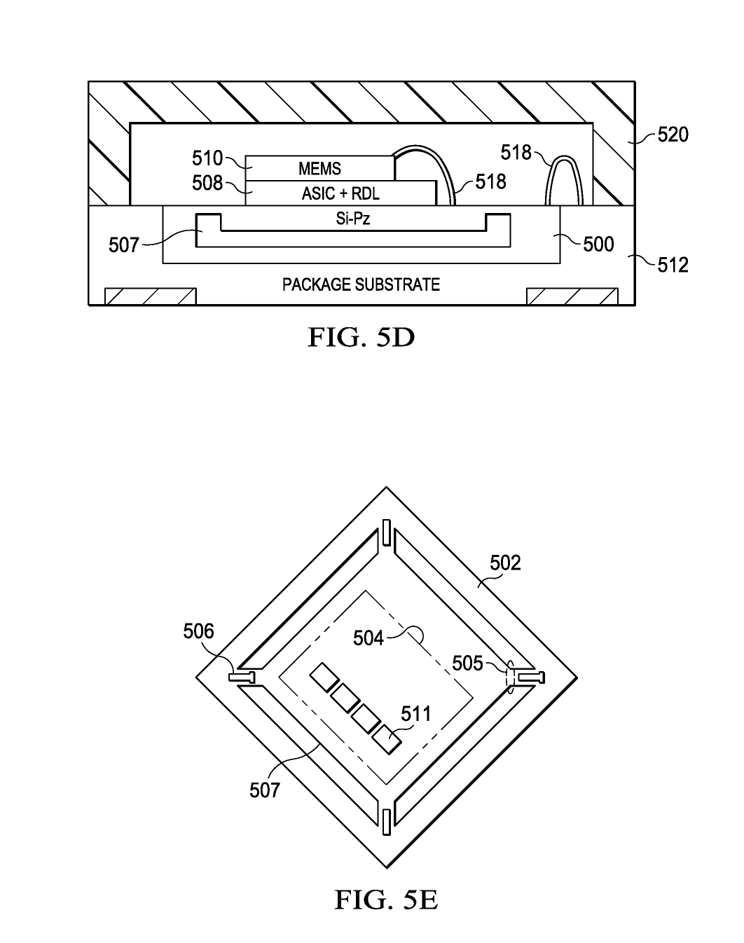

FIGS. 5A-5E are views of alternative embodiments of strain dies with integrated strain sensors, according to an embodiment. FIGS. 5A, 5C, 5D are cross-sectional views along the AA′ plane of FIG. 5B and FIGS. 5B and 5E are top views looking down on the strain die plane (a plane perpendicular to the AA′ plane) with the package stack removed.

Referring to FIGS. 5A and 5B, strain die 500 is made of silicon and includes body 502 and base 504. Base 504 is a silicon membrane that supports a package stack comprising ASIC die 508 and MEMS die 510. Base 504 provides a floating platform for the package stack mounted on top. Base 504 is suspended over undercut 507 by four mechanically compliant springs 505 which also act as strain enhancing structures. Base 504 and springs 505 act as an acoustical filter providing vibration isolation. Alternative embodiments may include more or fewer springs. Base 504 concentrates strain induced packaging effects around springs 505 (or other locations of maximum strain) so the effects can be sensed more effectively by strain sensors 506 disposed on springs 505 (e.g., doped PzR implants). Base 504 is shown with RDL layer 511 of ASIC die 508. Bond pads 517 shown in FIG. 5B disposed around body 504 route raw or processed strain signals and MEMS and ASIC signals to outside the package.

Referring to FIG. 5C, strain die 500 is embedded into package substrate 512 (e.g., an LGA substrate) to reduce the overall package height. Silicon cap 514 is bonded to strain die 500 and encloses ASIC die 508 and MEMS die 510. Silicon cap 514 prevents plastic mould 516 from entering undercut 507 formed in strain die 500. In an embodiment, MEMS die 510 is wire bonded to the strain die and the strain die is wire bonded to package substrate 512 using wire bonds 518 as shown in FIG. 5C. FIG. 5D is a cross-sectional view of strain die 500 with plastic lid 520 and no silicon cap 514. FIG. 5E is a top view of strain die 500 without wire bond pads 517.

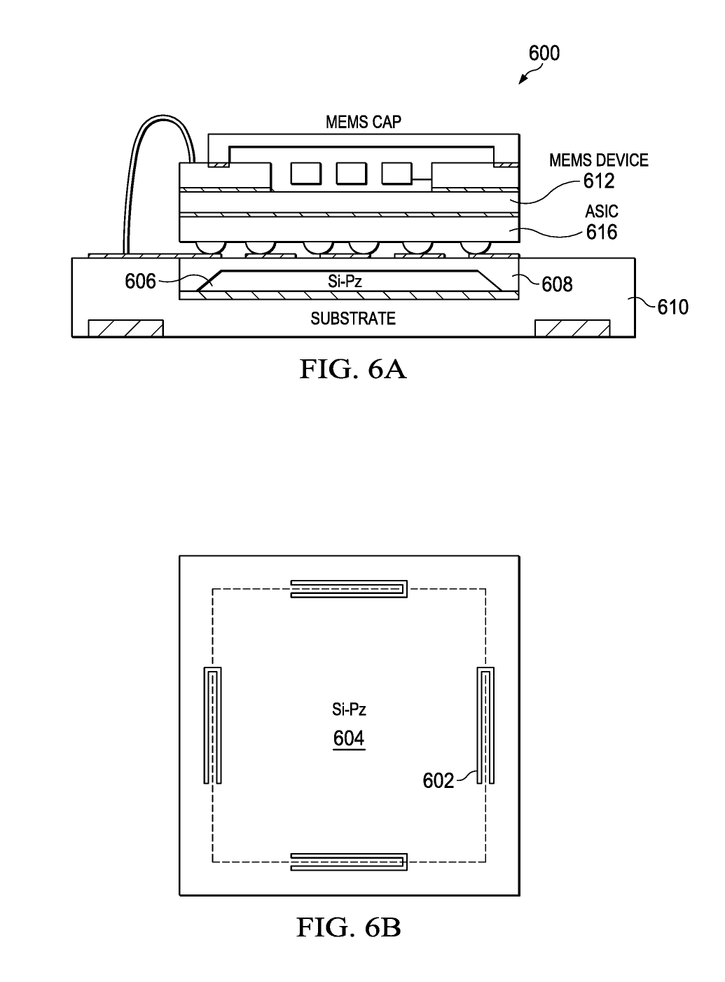

FIGS. 6A and 6B are views of package stack 600 with Si integrated PzR sensors in an etched diaphragm (FIG. 6B), where the PzR sensors are positioned at locations of maximum strain for better detection. Routing and passivation layers have been intentionally removed from FIG. 6B to simplify discussion. Doped PzR sensors 602 can be placed at maximum stress locations, such as at the four edges of diaphragm 604 as shown in FIG. 6B. Diaphragm 604 is a mechanically compliant material formed over undercut 606 formed in strain die 608. Embedding strain die 608 into package substrate 610 reduces the package height. In this design, package stack 600 includes MEMS die 612 and ASIC die 616 attached to MEMS die 612 using, for example, die attachment film (DAF). Package stack 600 is attached to strain die 608 by an ASIC RDL which is part of ASIC die 616 that makes I/O pads available in other locations of the package.

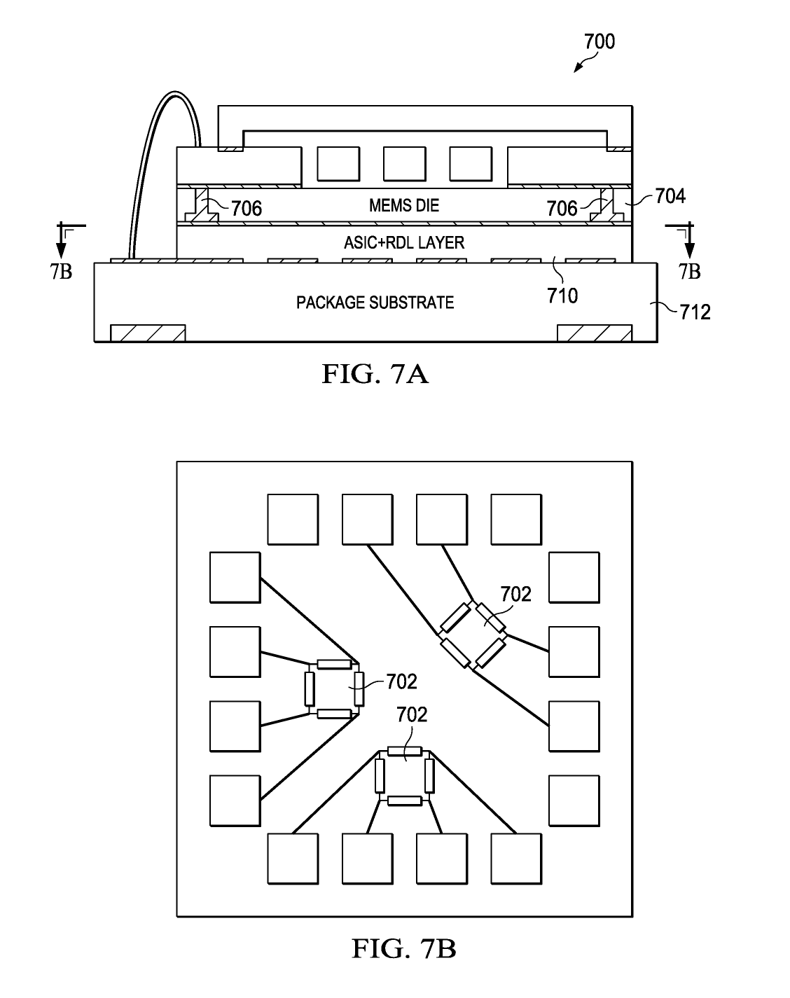

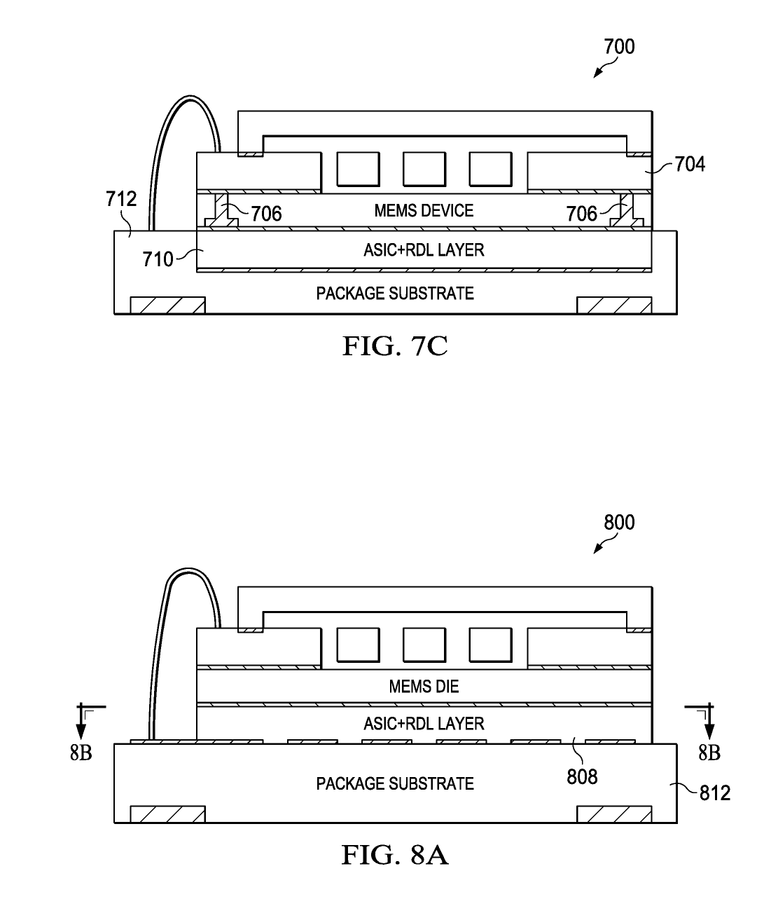

FIGS. 7A-7C are views of package stack 700 with strain sensors implanted on the back side of a MEMS die to detect strain. As shown in FIG. 7B, strain sensors 702 (e.g., Si-Pz) are ion implanted in a Rosette configuration on the back side of MEMSs die 704 to detect strain. As shown in FIG. 7A, TSVs 706 are used to electrically connect strain sensors 702 on the back side of MEMS die 704 to the top of ASIC die 710. Having strain sensors 702 included on MEMs die 704 does not add additional height to package stack 700 and eliminates the need for an additional strain die. In some implementations (FIG. 7C), ASIC die 710 can be embedded into package substrate 712 to further reduce the package height.

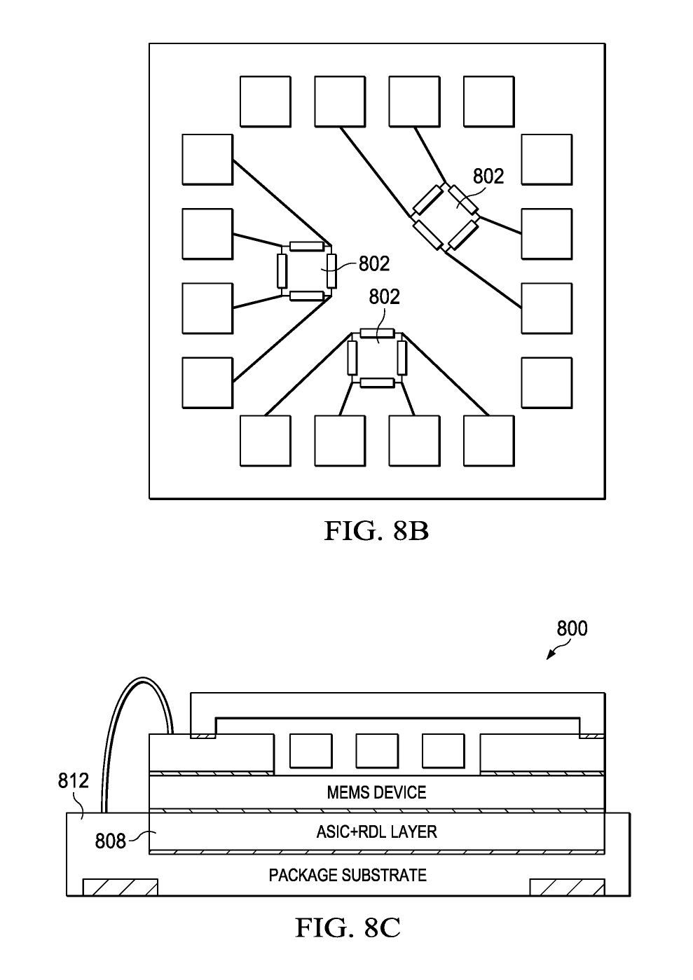

FIGS. 8A-8C are views of package stack 800 with strain sensors 802 implanted on the front side and back side of the ASIC die 808 to detect strain. As shown in FIG. 8B, strain sensors 802 (e.g., Si-Pz) are ion implanted in a Rosette configuration on the front and/or back side of ASIC die 808 to detect strain. Having strain sensors 802 included on ASIC die 808 does not add additional height to package stack 800 and eliminates the need for an additional strain die. In some implementations (FIG. 8C), ASIC die 808 can be embedded into package substrate 812 to further reduce the package height.

### Example Processes for Fabricating Strain Dies

FIGS. 9-1 to 9-14 is a process flow for fabricating a strain die to be embedded in a package substrate, according to an embodiment. Note that the ASIC metal layer/inter-metal dielectric (IMD) thicknesses are exaggerated in the z-axis.

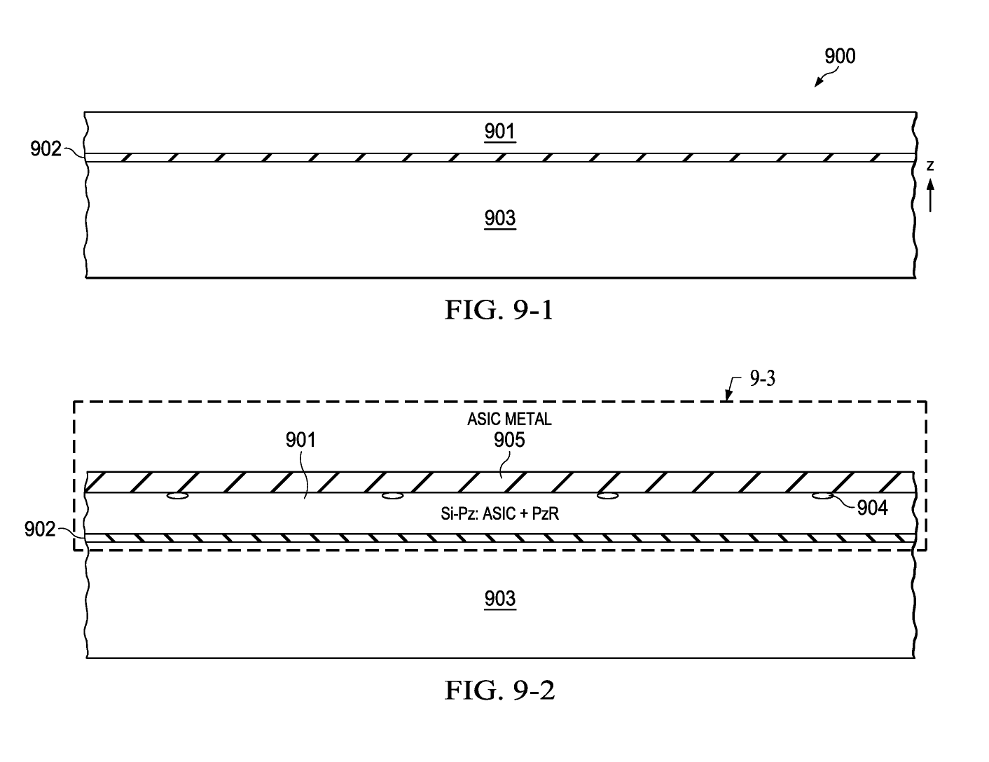

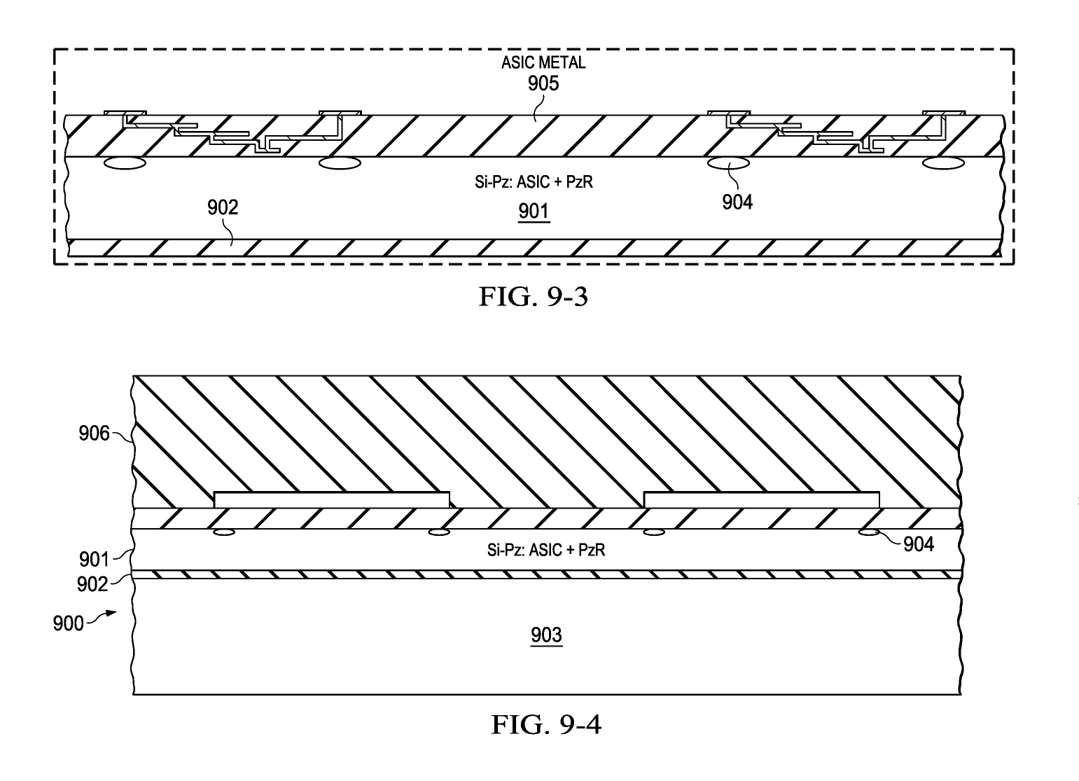

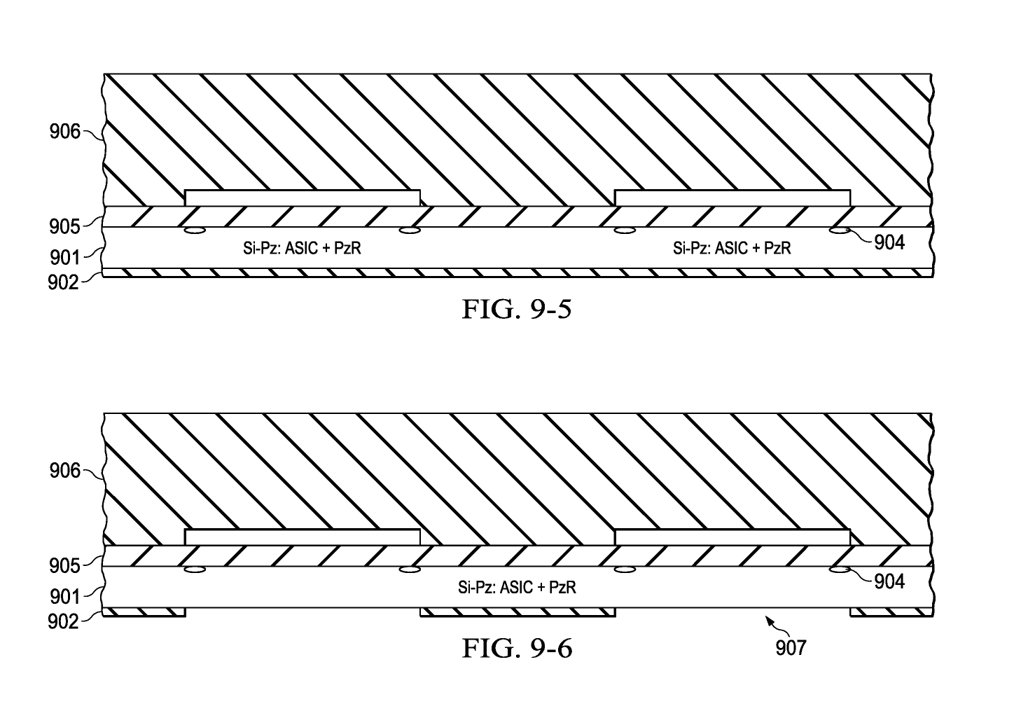

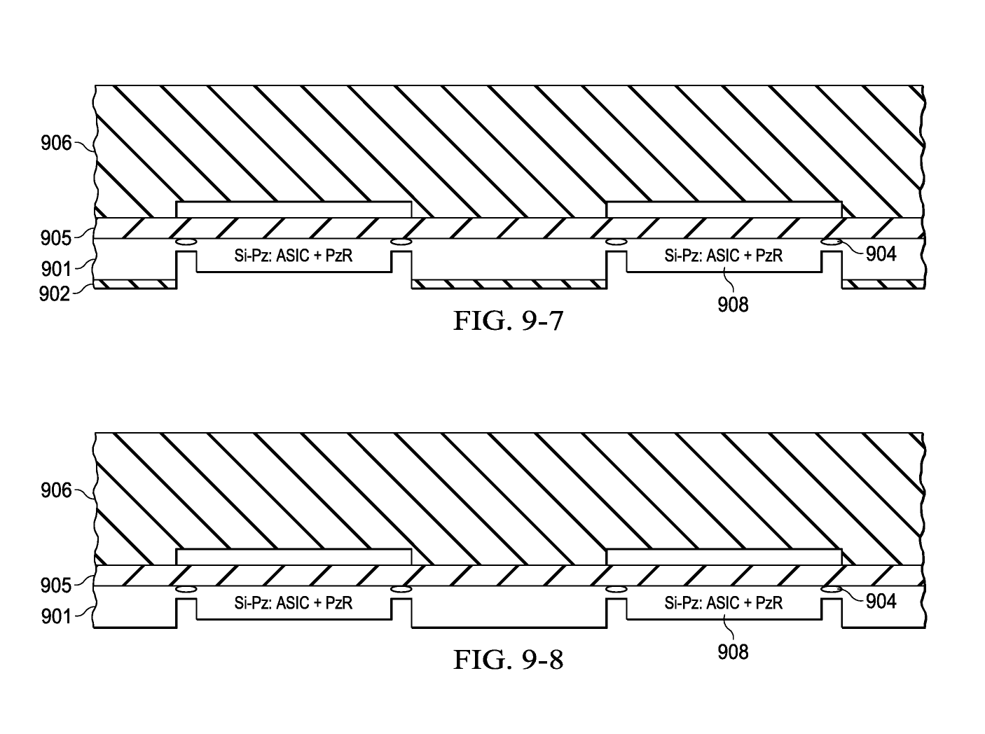

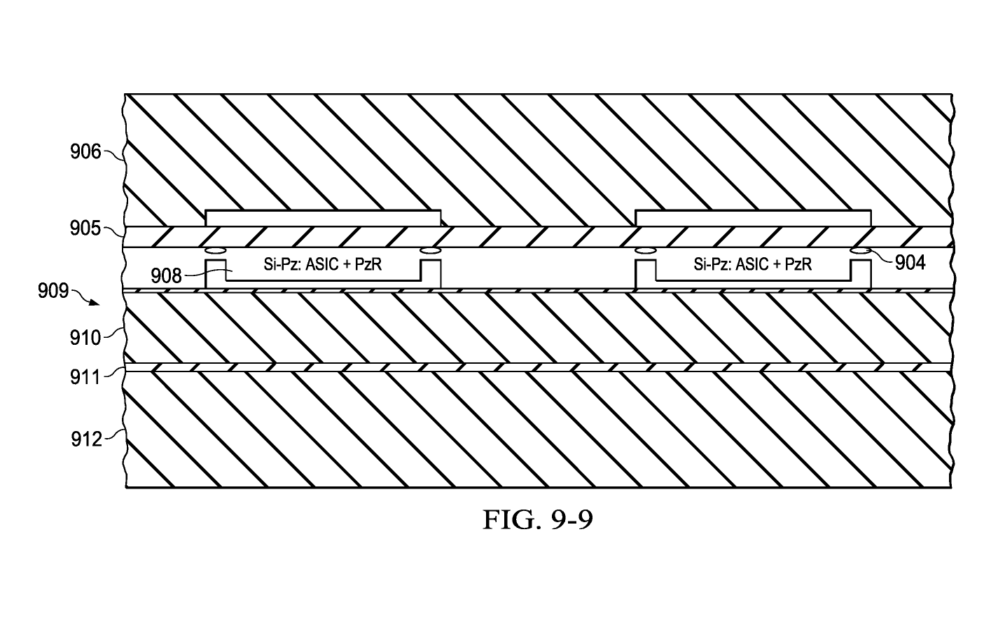

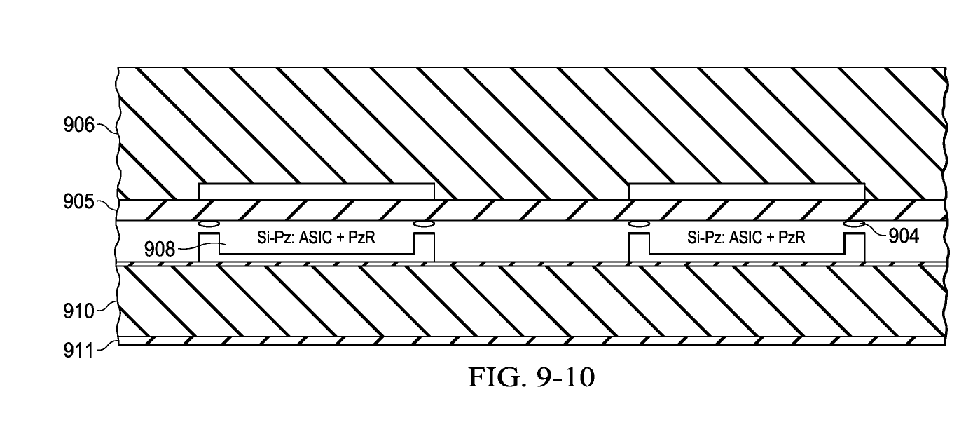

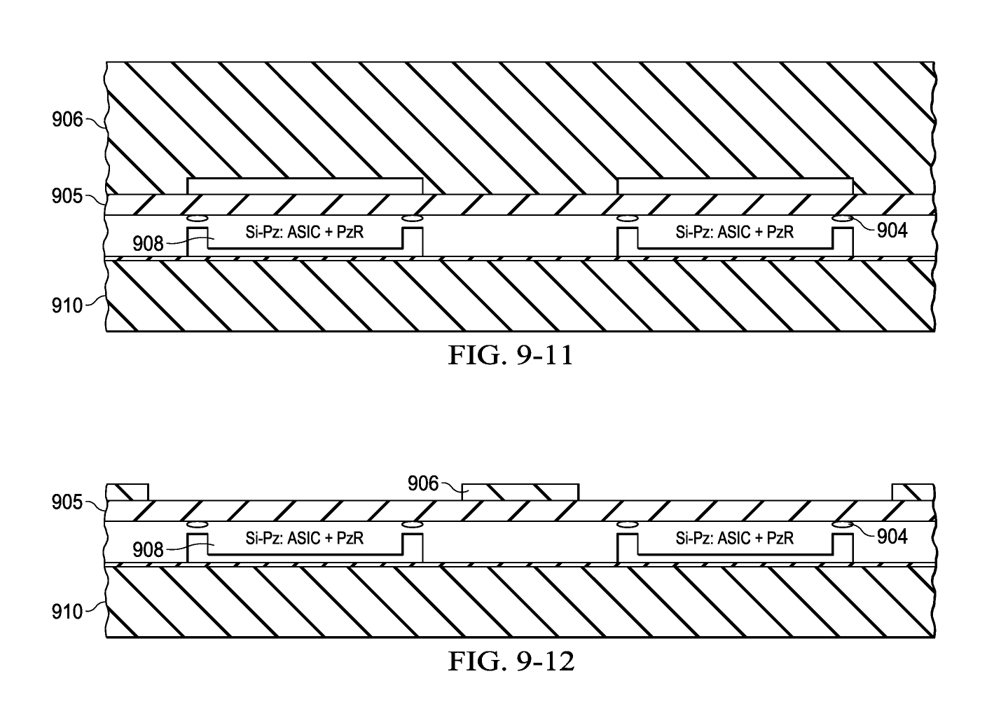

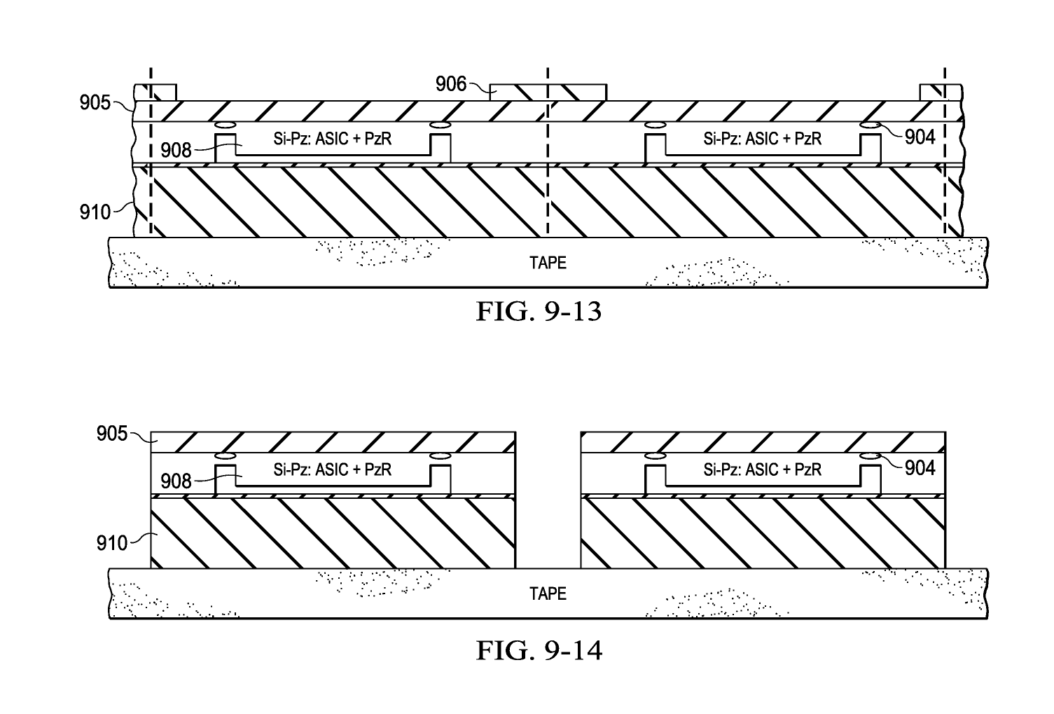

The process begins with first silicon-on-insulator (SOI) wafer 900 that includes first device layer 901, first buffered oxide (BOX) layer 902 and first SOI handle layer 903, as shown in FIG. 9-1. Piezo implants 904 and circuit metal layers 905 (e.g., ASIC metal layers and routing) are fabricated on first device layer 901, as shown in FIG. 9-2. Details of the metal/inter-layer dielectric (ILD) stack up is shown in FIG. 9-3.

Handle wafer 906 (shown patterned/etched using a first mask and deep reactive-ion etching (DRIE)) is bonded (e.g., with fusion bonding) onto first SOI wafer 900, as shown in FIG. 9-4. First SOI handle 903 is backside grinded and etched up to first BOX layer 902 using DRIE, as shown in FIG. 9-5. First BOX layer 902 is then dry etched (post CMOS process) using a second mask to pattern first BOX layer 902 to define embossed structure 907, as shown in FIG. 9-6. Another pattern dry etch on first BOX layer 902 form membrane structure 908, as shown in FIG. 9-7. A hydrofluoric acid (HF) wet etch is performed to remove the patterned first BOX layer 902, as shown in FIG. 9-8.

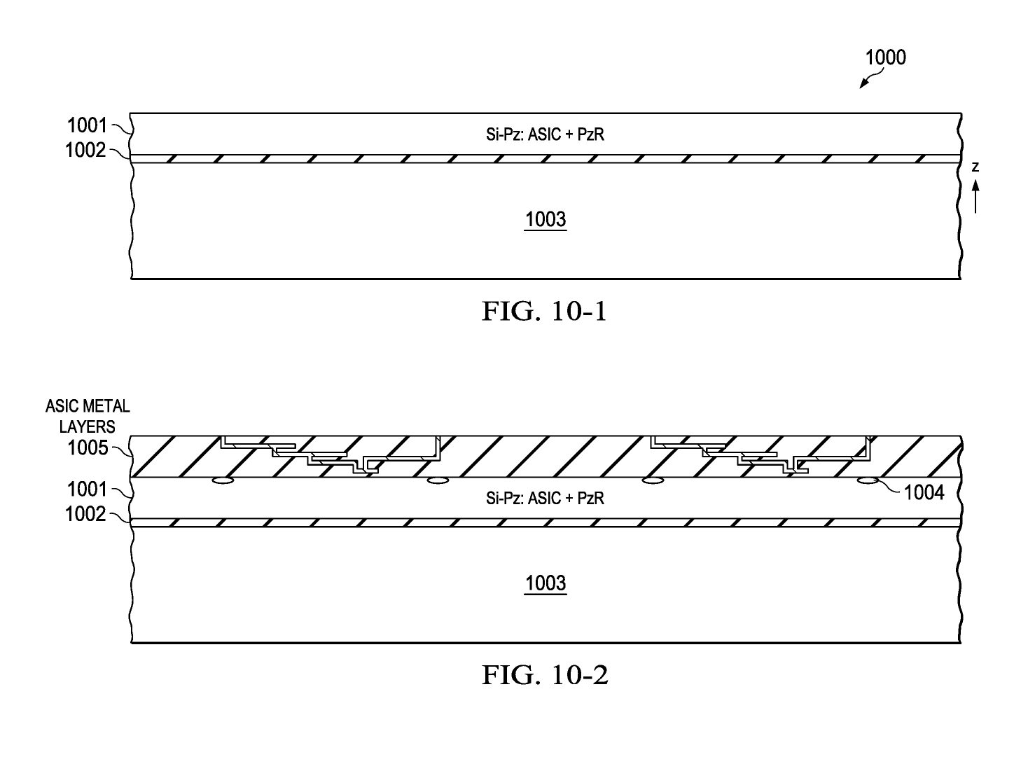

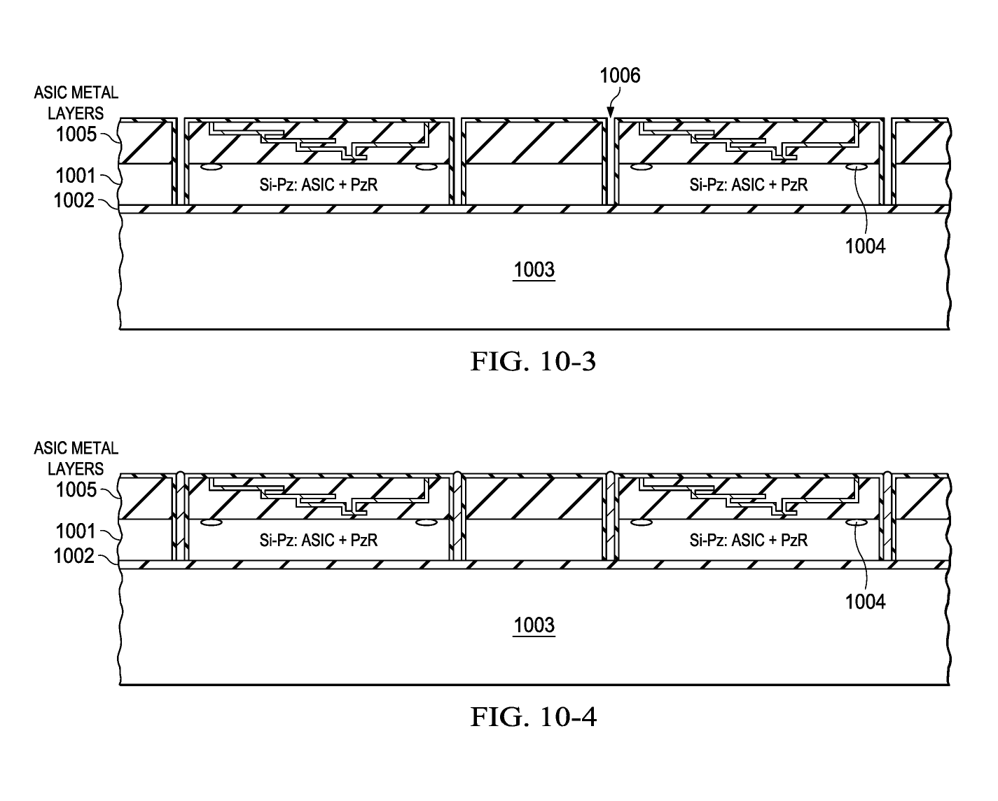

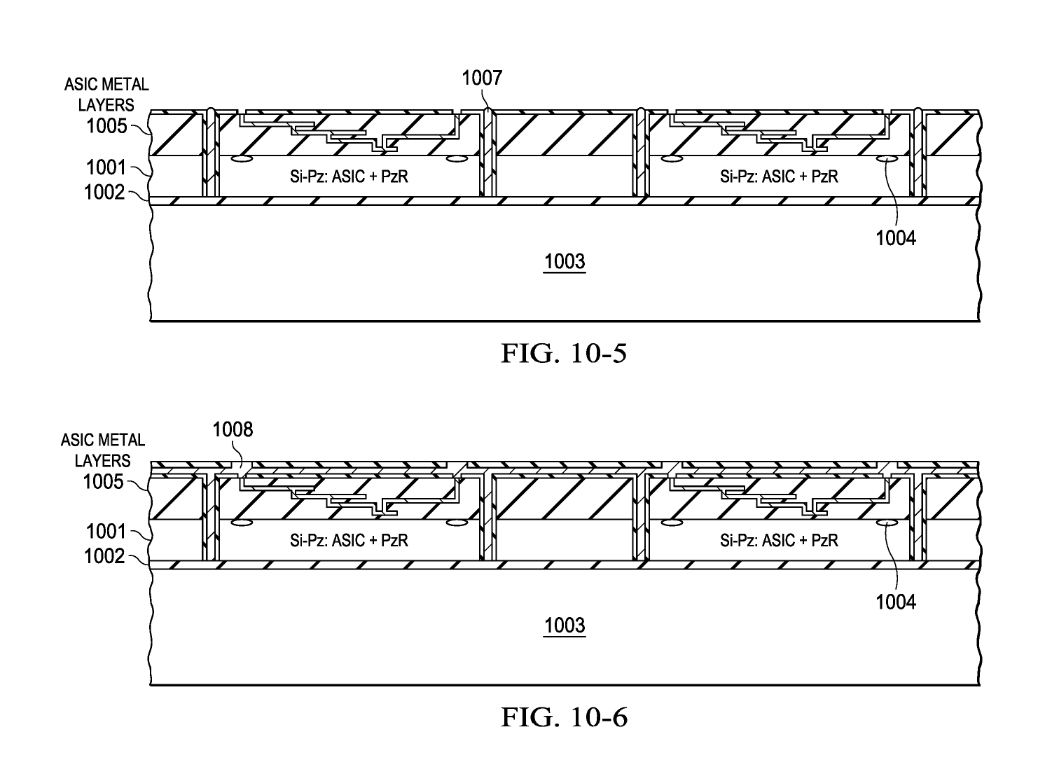

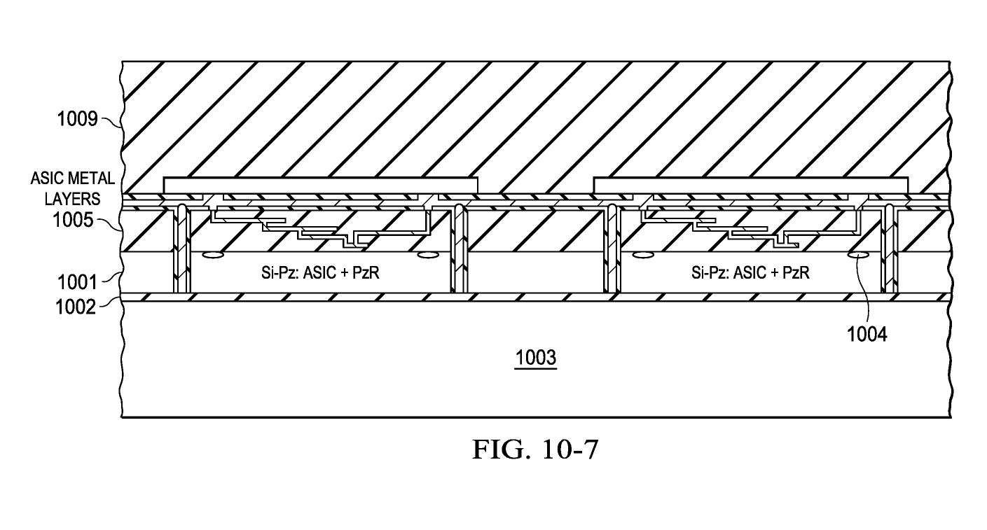

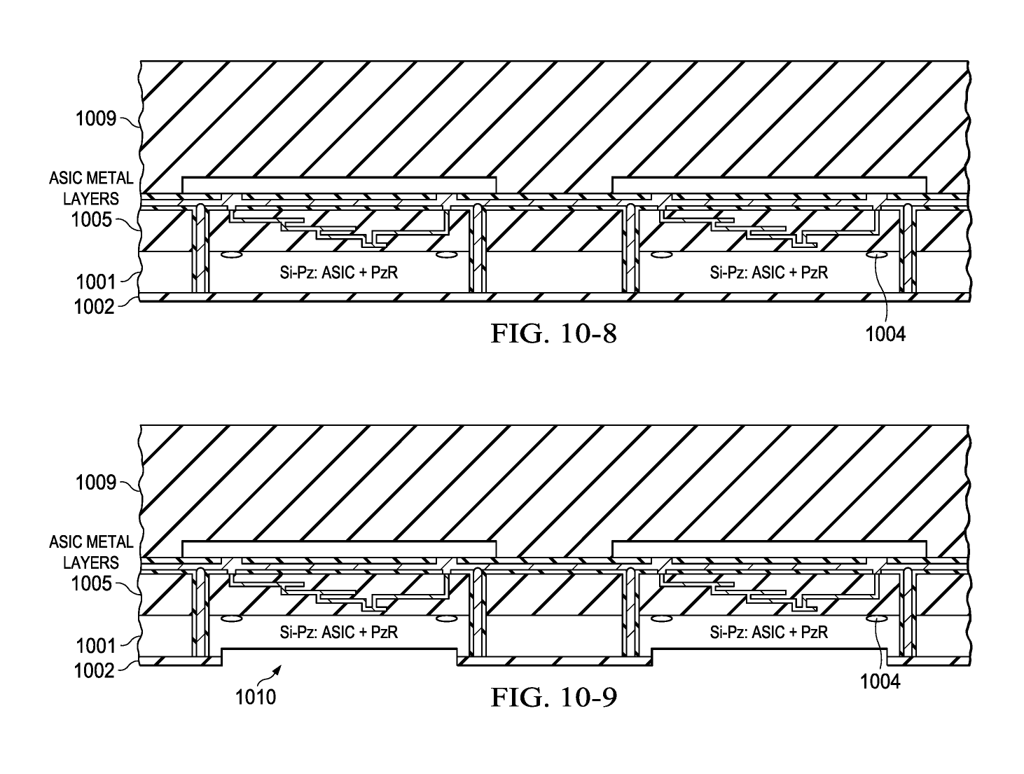

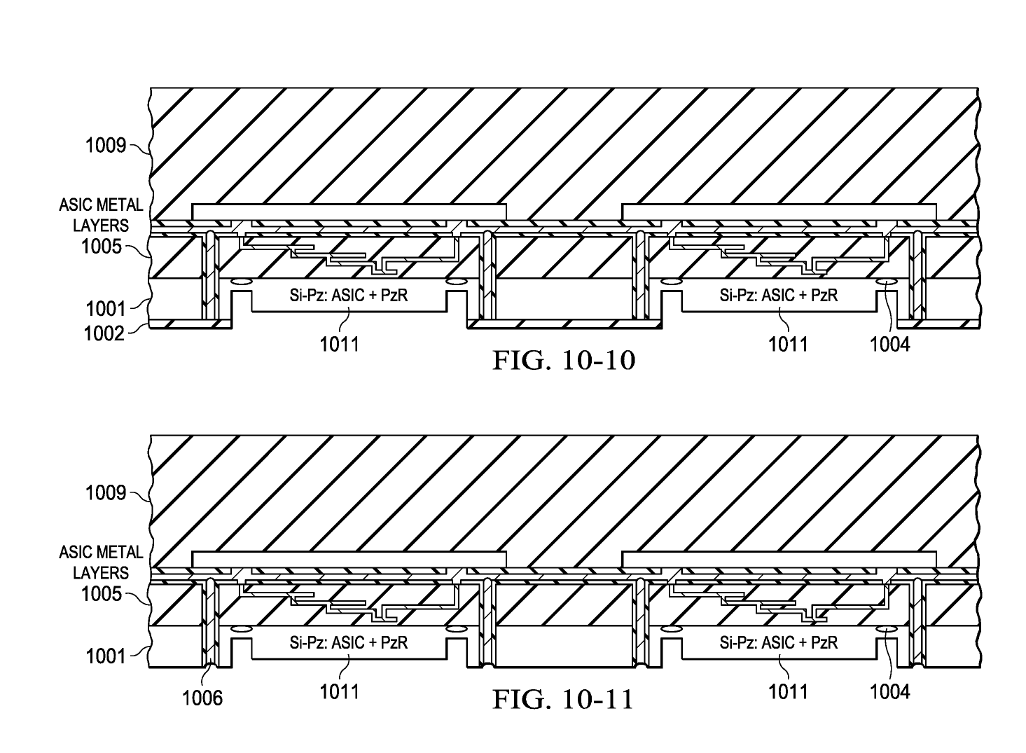

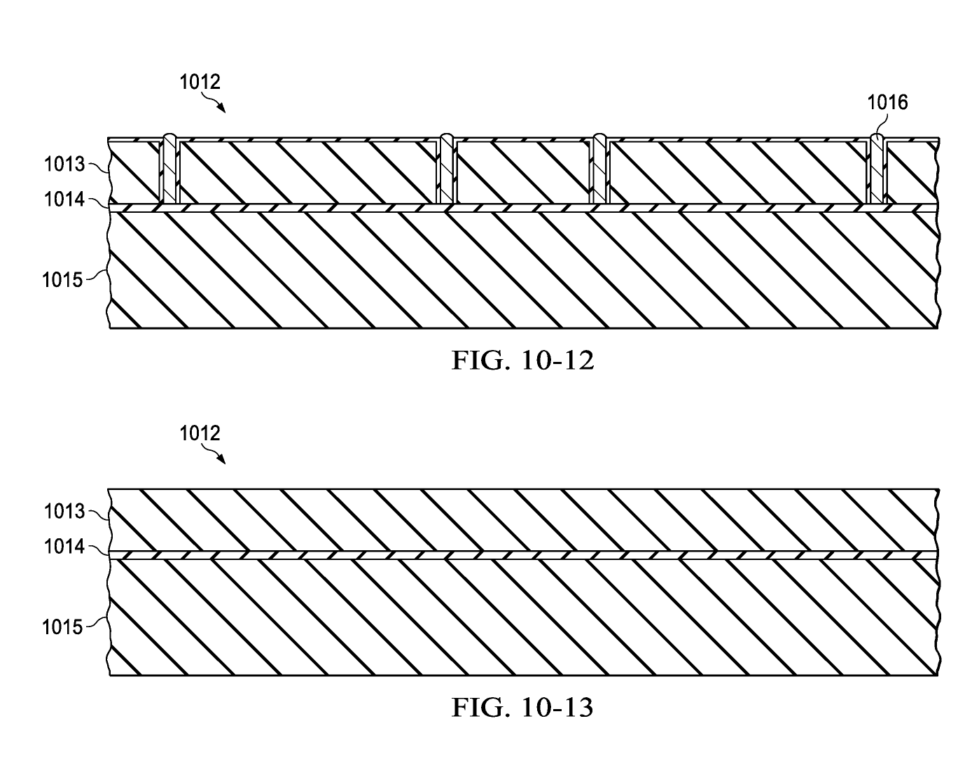

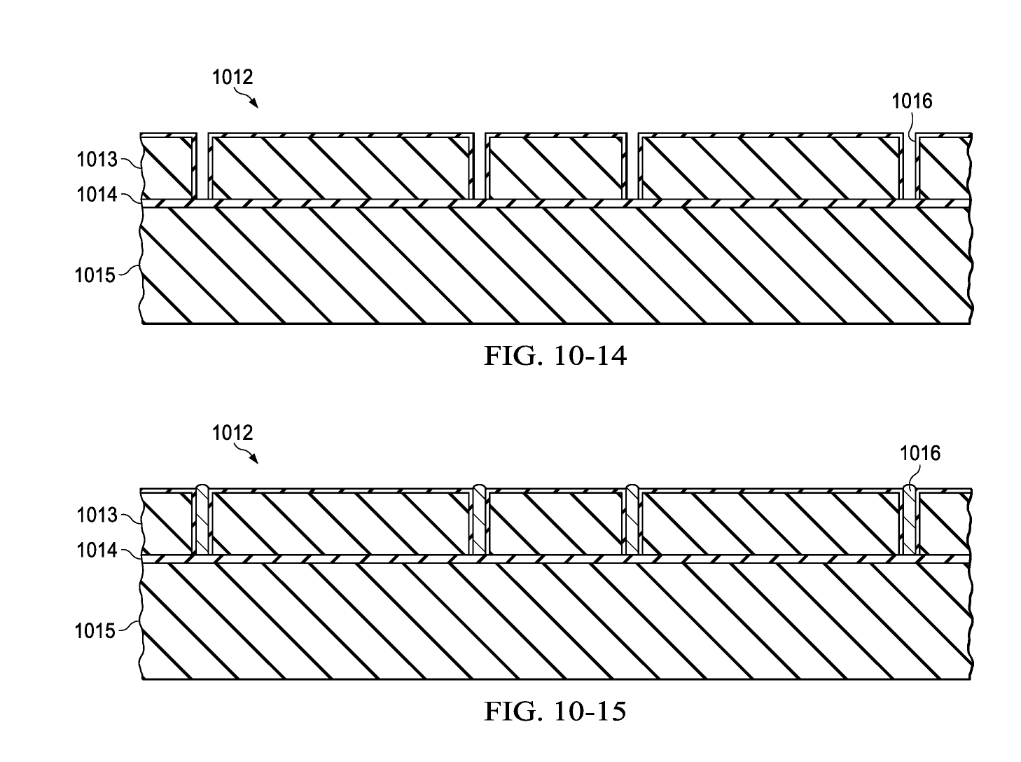

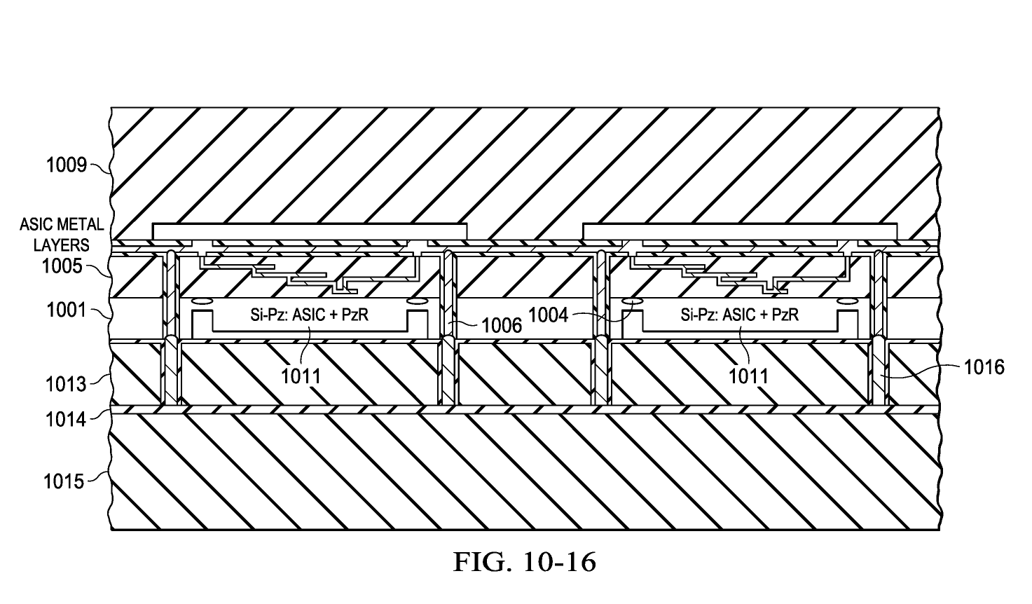

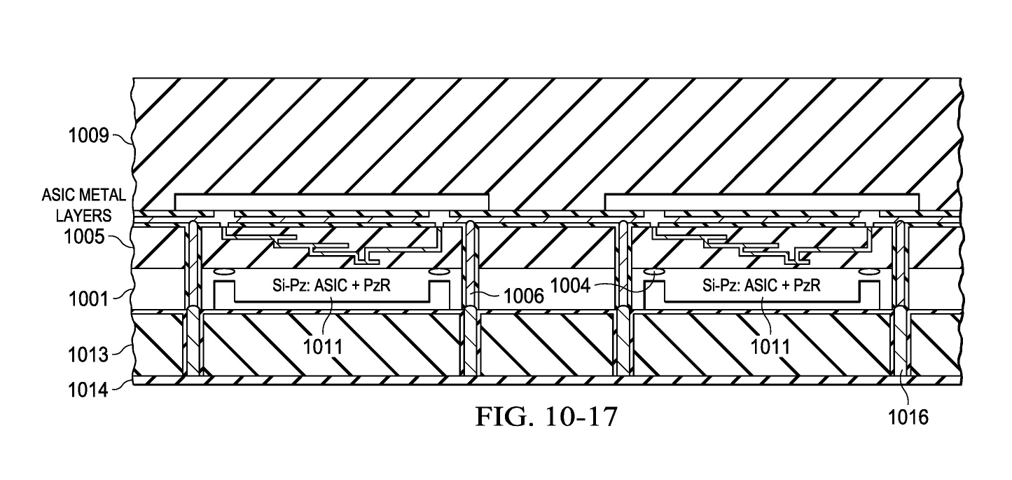

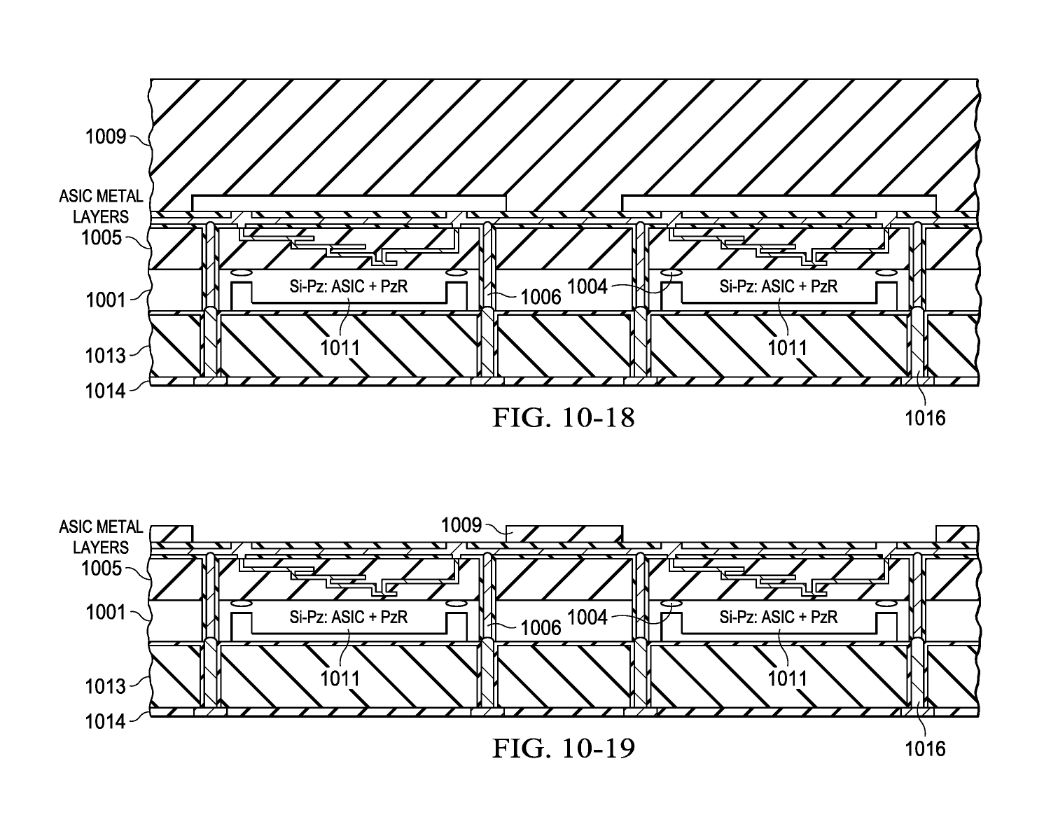

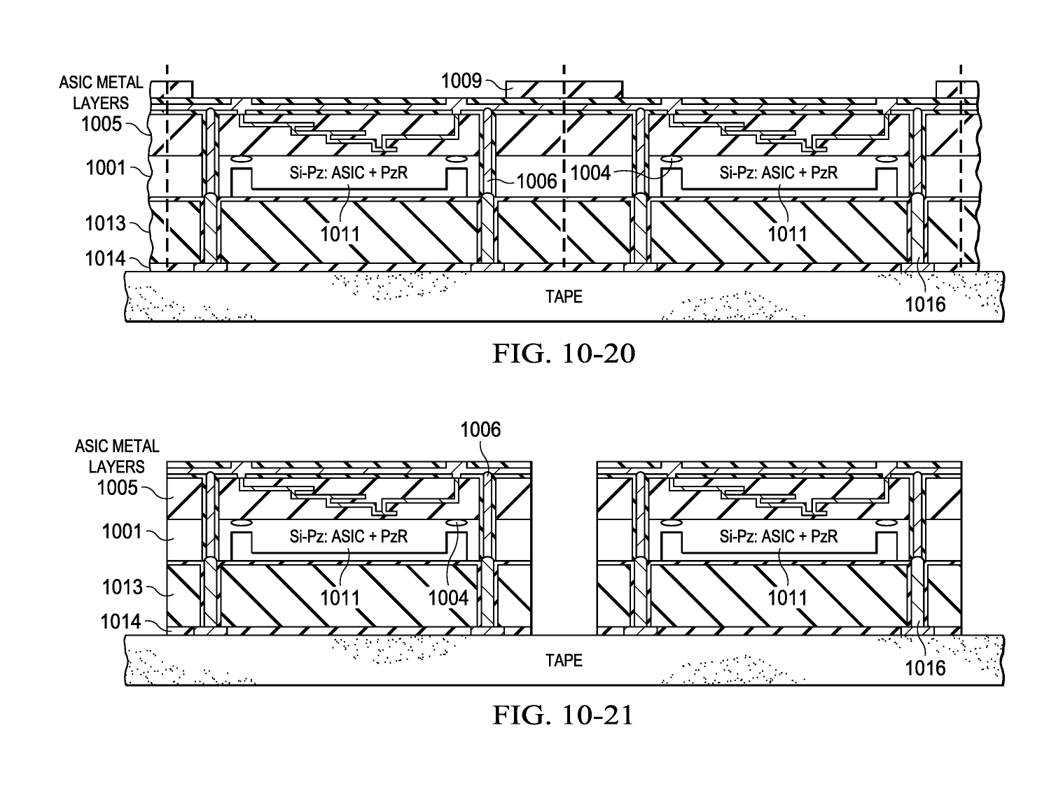

Second SOI wafer 909 including second device layer 910 (with thermal oxide on top), second BOX layer 911 and second SOI handle 912 is fusion bonded to first SOI wafer 900 to form a bottom wafer, as shown in FIG. 9-9. Second SOI handle 912 is backside grinded followed by DRIE to stop at the second BOX layer 911, as shown in FIG. 9-10. Another HF etch is performed to remove second BOX layer 911, as shown in FIG. 9-11. Handle wafer 906 is grinded, followed by DRIE to expose strain die (SI-Pz) structures, as shown in FIG. 9-12. The wafer is placed on tape and diced as shown in FIG. 9-13 to provide individual strain dies as shown in FIG. 9-14.

FIGS. 10-1 to 10-21 is a process flow for fabricating a strain die that also acts as a package substrate, according to an embodiment. Note that the ASIC metal layer/inter-metal dielectric (IMD) thicknesses are exaggerated in the z-axis.

The process begins with first SOI wafer 1000 that includes first device layer 1001, first BOX layer 1002 and first SOI handle layer 1003, as shown in FIG. 10-1. Piezo implants 1004 and circuit metal layers 1005 (e.g., ASIC metallization and routing) are fabricated on first device layer 1001, as shown in FIG. 10-2. First TSVs 1006 are formed by DRIE after the circuit metal layers 1005 and a passivation layer are fabricated, as shown in FIG. 10-3. A metallization step fills the first TSVs 1006 with metal inter-connect, as shown in FIG. 10-4.

Next, the top passivation layer in the circuit metal layer is patterned to expose top metal 1007, followed by sputtering for making TSV to ASIC connections, as shown in FIG. 10-5. Metal is sputter/patterned to form bond pads 1008 for external connection, as shown in FIG. 10-6.

Next, handle wafer 1009 (patterned/etched using a first mask and DRIE) is bonded (e.g., with fusion bonding) onto first SOI wafer 1000 to enable backside processing, as shown in FIG. 10-7. SOI handle layer 1003 is backside grinded and etched up to first BOX layer 1002 using DRIE, as shown in FIG. 10-8. First BOX layer 1002 is patterned with a second mask and dry etched (post CMOS process) to define embossed structure 1010, as shown in FIG. 10-9. Another pattern dry etch (post CMOS DRIE step) is performed to form membrane structure 1011, as shown in FIG. 10-10. A HF wet etch is performed to remove unwanted portions of patterned BOX layer 1002 and expose metallization of first TSVs 1006 on the bottom side of first SOI wafer 1000, as shown in FIG. 10-11.

As shown in FIG. 10-12, second SOI wafer 1012 (with thermal oxide and TSVs 1016) forms a bottom wafer. Second SOI wafer 1012 includes second device layer 1013, second BOX layer 1014 and second SOI handle layer 1015. Second TSVs 1016 are formed in second SOI wafer 1012, followed by conformal thermal oxidation and metallization of second TSVs 1016, as shown in FIGS. 10-14 and 10-15, respectively.

After second SOI wafer 1012 is fabricated it is fusion bonded to the top of first SOI wafer 1000, making sure there is electrical contact between the top and bottom TSVs 1006, 1016, as shown in FIG. 10-16. Second SOI handle layer 1015 is backside grinded, followed by DRIE up to second BOX layer 1014, as shown in FIG. 10-17. Second BOX layer 1014 is patterned by dry etching, followed by a metallization step at the TSV regions, as shown in FIG. 10-18. Handle wafer 1009 is grinded, then DRIE is used to expose strain die (SI-Pz) structures, as shown in FIG. 10-19. Finally, the wafer is placed on tape and diced as shown in FIG. 10-20 to provide individual strain die as shown in FIG. 10-21.

A number of implementations have been described. Nevertheless, it will be understood that various modifications may be made. Elements of one or more implementations may be combined, deleted, modified, or supplemented to form further implementations. As another example, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other implementations are within the scope of the following claims.

What is claimed is:

1. An integrated circuit (IC) package comprising:
a substrate having a body and a base;
a strain enhancing structure formed on the substrate, the strain enhancing structure mechanically isolating the base from the body and decoupling strain from the package; and
one or more strain sensors disposed on or proximate to the strain enhancing structure, the one or more strain sensors generating a strain signal in response to package strain.

2. The IC package of claim 1, wherein the strain enhancing structure is a mechanically compliant membrane that surrounds the body and couples the base to the body.

3. The IC package of claim 2, wherein the one or more strain sensors are located at least partially on one or more edges of the mechanically compliant membrane.

4. The IC package of claim 2, wherein the strain enhancing structure includes one or more undercut springs that couple the base to the body.

5. The IC package of claim 4, wherein the one or more strain sensors are formed at least partially on the one or more undercut springs.

6. The IC package of claim 2, wherein the base is undercut and the strain enhancing structure includes one or more undercut springs coupling the base to the body.

7. The IC package of claim 6, wherein the one or more strain sensors are formed at least partially on the one or more undercut springs.

8. The IC package of claim 1, wherein at least one of the one or more strain sensors is a piezo-resistor.

9. The IC package of claim 1, further comprising:
a package stack including one or more sensors mounted on the base.

10. The IC package of claim 9, wherein the package stack includes a micro-electrical-mechanical system (MEMS) die attached to an application-specific integrated circuit (ASIC) die.

11. The IC package of claim 10, wherein the ASIC die includes a redistribution layer (RDL) that is flip chip bonded to the base.

12. The IC package of claim 1, further comprising:
a redistribution layer formed in the substrate operable for routing one or more strain signals from the one or more strain sensors to circuitry in the IC package or outside the IC package.

13. The IC package of claim 1, further comprising:
a silicon cap covering the substrate; and
plastic mould covering the silicon cap.

14. The IC package of claim 1, further comprising:
a plastic cap covering the substrate.

15. The IC package of claim 1, wherein the substrate includes wire bond pads.

16. The IC package of claim 1, further comprising:
a package substrate attached to the substrate.

17. The IC package of claim 1, wherein the substrate includes through silicon vias (TSVs) to allow connectivity outside the IC package.

18. The IC package of claim 1, further comprising:
a package substrate configured to receive the substrate so that the substrate is embedded at least partially in the package substrate.

19. A method of fabricating a strain die with integrated strain sensors, the method comprising:
forming piezo implants and one or more circuit metal layers on a topside of a first silicon on insulator (SOI) wafer, where the first SOI wafer includes a first buffered oxide (BOX) layer and a first SOI handle layer;
bonding a handle wafer to the topside of the first SOI wafer,
removing the first SOI handle layer up to the first BOX layer;
forming an embossed structure in the first device layer;
forming a membrane structure in the first device layer;
removing unwanted portions of the patterned first BOX layer;
bonding a second SOI wafer to the bottom side of first SOI wafer, the second SOI wafer including a second device layer, a second BOX layer and a second SOI handle layer;
grinding the second SOI handle layer up to the second BOX layer;
removing unwanted portions of the second BOX layer; and
removing at least a portion of the handle wafer to expose a plurality of strain die including the embossed and membrane structures.

20. A method of fabricating a strain die with integrated strain sensors, the method comprising:
forming piezo implants and a circuit metal layer on a first device layer of a first silicon-on-insulator (SOI) wafer, where the first SOI wafer includes the first device layer, a first buffered oxide (BOX) layer and a first SOI handle layer;
forming first through silicon vias (TSVs) in the circuit metal layer and first device layer;
filling the first TSVs with metal inter-connect;
exposing metal of the circuit metal layer;
forming electrical connections between the first TSVs and the circuit metal layer;
forming bond pads on the circuit metal layer;
bonding a handle wafer onto the first SOI wafer;
removing the first SOI handle layer up to the first BOX layer;
forming an embossed structure in the first device layer;
forming a membrane structure in the first device layer;
removing portions of the first BOX layer to expose TSVs;
bonding a second SOI wafer to the first SOI wafer, the second SOI wafer including a second device layer, a second BOX layer and a second SOI handle layer, the second device layer further including second TSVs, wherein the bonding includes aligning the first and second TSVs to ensure electrical contact;
removing at least a portion of the second SOI handle layer up to the second BOX layer; and
exposing metal of the second TSVs; and
removing at least a portion of the handle wafer to expose a plurality of strain dies that include the embossed and membrane structures.
